(19) United States
(12) Patent Application Publication
(10) Pub. No.: US 2008/0135527 A1
(43) Pub. Date: Jun. 12, 2008

(54) SUPERALLOY MICRO-HEATING APPARATUS AND METHOD OF MANUFACTURING THE SAME

(76) Inventor: Yu-Fu Kang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/736,594

(22) Filed: Apr. 18, 2007

(30) Foreign Application Priority Data
Dec. 11, 2006 (TW) 095146267

(51) Int. Cl. H05B 1/00; C23C 14/04

(52) U.S. Cl. 219/50; 204/192.12

(57) ABSTRACT

A superalloy micro-heating apparatus includes a substrate, an isolation layer on a front surface of the substrate, a patterned heating resistor, and a contact electrode on the heating resistor. The material of the heating resistor includes superalloy material that has the advantages of corrosion-resistance, high-resistance, rapid-thermal increase, and high-temperature resistance. For these reasons, the superalloy micro-heating resistor has an improved reliability and yield.

### BACKGROUND OF THE INVENTION

1. Field of the Invention

The invention relates to a micro-heating apparatus, and particularly, to a micro-heating apparatus comprising superalloy as material.

2. Description of the Prior Art

Micro-electro mechanical systems (MEMS) devices are mechanical devices utilizing semiconductor-processing techniques to manufacture mechanical devices of sizes as small as a micrometer. Several elements may be incorporated into the MEMS devices, so that MEMS devices may be utilized in multiple industries, such as optical, electronics, electrical engineering, material, physics, chemistry and bio-medical industries.

Micro-heating apparatus manufactured by MEMS processes are commonly utilized devices. For example, a conventional micro-heating apparatus is a component of a print head. When a current passes through the resistor of the micro-heating apparatus in the print head, the micro-heating apparatus boils ink and bursts the ink out of the print head for printing. The conventional micro-heating apparatus is also found in biochips. A micro-heating apparatus in biochips controls the temperature of a sample in a reactor when it undergoes a reaction or during sample detection. Both the micro-heating apparatus of the print head and the biochips are used for thermal control.

The conventional micro-heating apparatus utilizes a high-resistance metal as the material of the heating resistor. After some period of time, heat and electron wind generated by current transfer the atoms of the heating resistor. Consequently, the grain boundary of the heating resistor is reduced and stress is increased, destroying the grain boundary. Therefore, a shortcut circuit of the heating resistor is formed. This is the so-called “electromigration effect”, which is a major factor in reducing the reliability and lifetime of the micro-heating apparatus.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

Since a conventional micro-heating apparatus has an electromigration problem that reduces reliability of the conventional micro-heating apparatus, a primary objective of the present invention is to provide a superalloy micro-heating apparatus to solve these problems. The superalloy micro-heating apparatus of the present invention includes a substrate, an isolation layer positioned on a front surface of the substrate, a heating resistor of superalloy materials disposed on the isolation layer, and a contact electrode positioned on the heating resistor.

Another objective of the present invention is to disclose a method of manufacturing a superalloy micro-heating apparatus. A substrate and a superalloy-sputtering target are provided and positioned respectively at an anode and a cathode of a sputtering system. The anode of the sputtering system is electrically connected to a back surface of the substrate. The substrate has an isolation layer and a patterned photoresist on a front surface thereof. A sputtering process is performed to form a superalloy film on the surface of the isolation layer and the patterned photoresist. A lift-off process is performed to remove the patterned photoresist so that the superalloy film is patterned to form a heating resistor.

Superalloy has the crucial properties of withstanding extreme temperatures, creep resistance at high temperatures, and excellent mechanical strength. The micro-heating apparatus of the present invention utilizes superalloy as a material, and accordingly, the micro-heating apparatus of the present invention has better reliability and longer lifetime than conventional micro-heating apparatus.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 through 6 are schematic diagrams illustrating a method of manufacturing a micro-heating apparatus according to a first embodiment of the present invention.

FIGS. 7 through 9 are schematic diagrams illustrating another method of manufacturing a micro-heating apparatus according to a second embodiment of the present invention.

### DETAILED DESCRIPTION

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

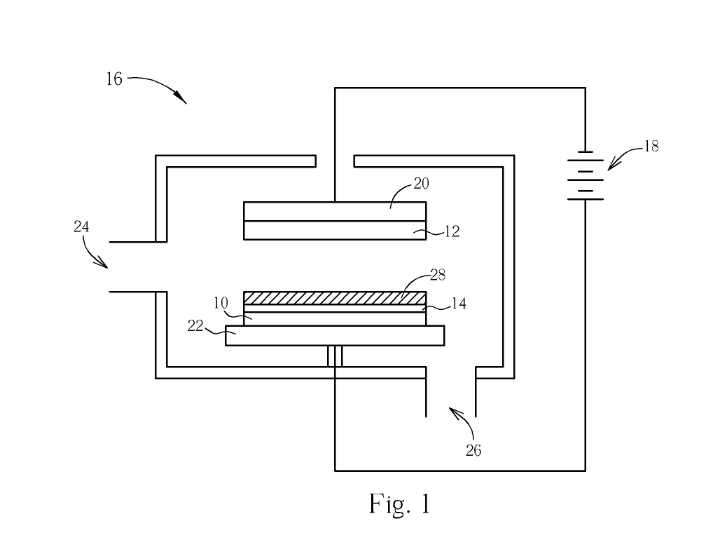

Please refer to FIGS. 1 through 6, which are schematic diagrams showing a method of manufacturing a micro-heating apparatus according to a first embodiment of the present invention. Initially, a substrate 10 and a superalloy-sputtering target 12 are provided. The substrate 10 has an isolation layer 14 on a front surface thereof. The substrate 10 of the first embodiment is a silicon substrate but other kinds of substrates are allowable. The superalloy-sputtering target 12 may comprise Inconel, Nimonic, Incoloy, Invar, Illium, NX-188, or combinations thereof. The substrate 10 and the superalloy-sputtering target 12 are positioned inside a sputtering system for a subsequent sputtering process. As shown in FIG. 1, a DC sputtering system has a sputtering chamber 16, a DC power supply 18, an anode 20, and a cathode 22. The superalloy-sputtering target 12 is electrically connected to the cathode 22 and a back surface of the substrate 10 is electrically connected to the anode 20 in the sputtering chamber 16. The sputtering chamber 16 further has a first opening 24 and a second opening 26. The plasma for the sputtering process, such as helium or argon, is provided through the first opening 24. The second opening 26 is connected to a pump (not shown), which maintains the vacuum of the sputtering chamber 16 during the sputtering process. At the beginning of the sputtering process, the pump creates a vacuum in the sputtering chamber 16. The pressure inside the sputtering chamber 16 is originally about 10⁻⁵ to 10⁻⁶ Torr, where a lower pressure of about 10⁻⁸ to 10⁻⁹ Torr is preferred. Then, a current is supplied by the DC power supply 18 on the anode 20 and the cathode 22. The positive ions of the plasma bombard the superalloy-sputtering target 12 and transfer momentum to the atoms on the surface of the superalloy-sputtering target 12. These atoms sputter from the surface of the superalloy-sputtering target 12 and shift to the substrate 10 at the anode 20. Therefore, a superalloy film 28 on the front surface of the substrate 10 is formed.

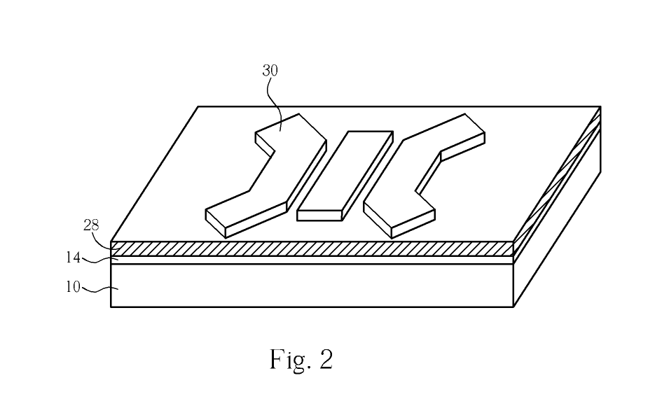

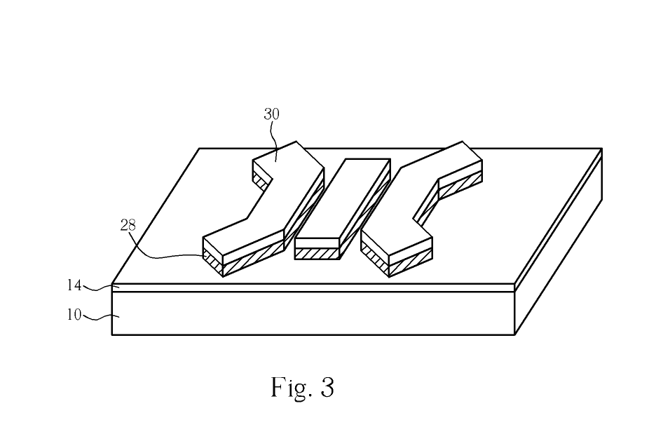

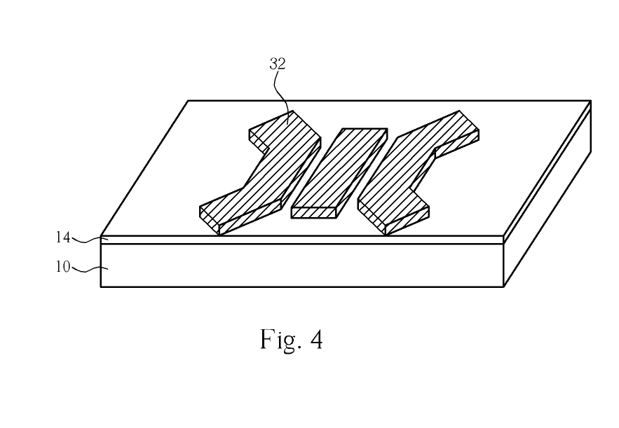

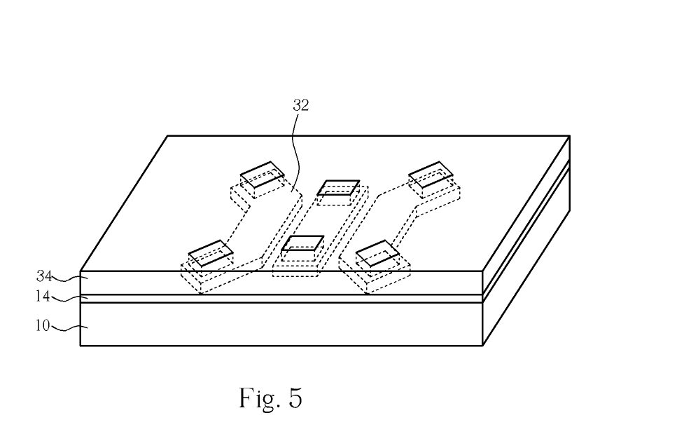

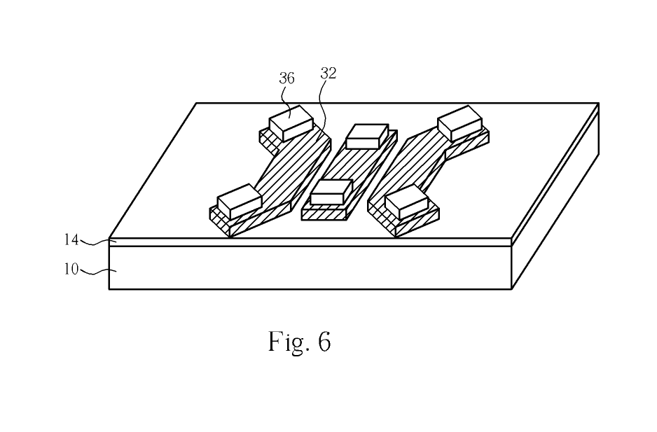

As shown in FIG. 2, a photoresist (not shown) is formed on the superalloy film 28. A lithography process is performed to define a pattern on the photoresist in order to form a patterned photoresist 30 on the substrate 10. As shown in FIG. 3, an etching process is performed, such as a dry etching process or a wet etching process. The patterned photoresist 30 is utilized as a mask to pattern the superalloy film 28 during the etching process. As shown in FIG. 4, the patterned photoresist 30 is removed and the patterned superalloy film 30 is exposed. The patterned superalloy film 30 is a heating resistor 32 of the micro-heating apparatus of the present invention. Hereinafter, a second photoresist 34 is formed on the heating resistor, and is patterned by a second lithography process for defining the size and the position of the contact electrode, as shown in FIG. 5. As shown in FIG. 6, a deposition process is performed to form a metal layer (not shown) including gold (Au), platinum (Pt), chromium (Cr), titanium (Ti), or combinations thereof. A lift-off process is performed to remove the second photoresist 34 and a part of the metal layer to form a contact electrode 36 on the heating resistor 32. The steps of forming the contact electrode 36 are not limited to those steps described above. The metal layer may be formed before the patterned photoresist and be patterned by an etching process. After that, the patterned photoresist is removed to expose the contact electrodes.

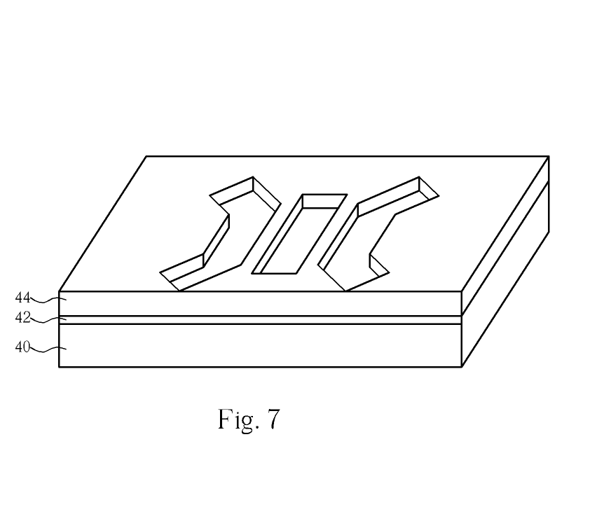

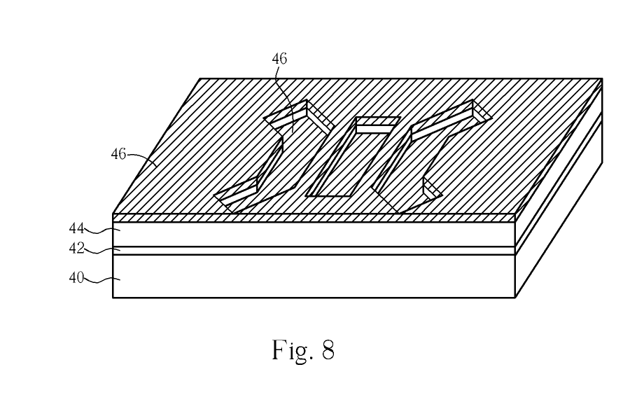

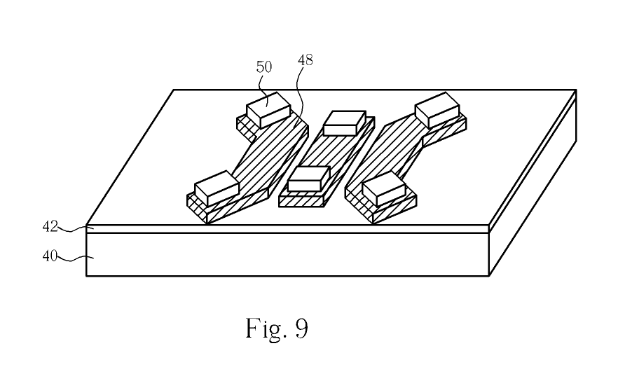

Furthermore, another method of manufacturing a micro-heating apparatus according to a second embodiment of the present invention will be described with reference to FIGS. 7 through 9. As shown in FIG. 7, a substrate 40 having an isolation layer 42 and a patterned photoresist 44 on a front surface is provided. The isolation layer 40 may comprise silicon oxide having good thermal isolation property. The patterned photoresist 40 is formed by the steps of photoresist formation and lithography process to define the position and the size of the heating resistor of the present invention. As shown in FIG. 8, a sputtering process is performed to form a superalloy film 46 covering the patterned photoresist 44. The sputtering process is performed utilizing the same sputtering system illustrated in FIG. 1. As shown in FIG. 9, a lift-off process is performed to remove the patterned photoresist 44 and a part of the superalloy film 46 positioned on the patterned photoresist 44. Therefore, the remaining superalloy film 46 has a pattern that forms a heating resistor 48. In addition, a contact electrode 50 is formed on the heating resistor as in the steps illustrated in FIG. 5 and FIG. 6.

The micro-heating apparatus may be combined with a chamber, such as an ink chamber of a print head, or a reaction chamber of a biochip. The contact electrode has a lower resistance than that of the heating resistor. Thus, the current is converted to heat by the heating resistor to warm up fluid in the above-mentioned chambers. The appearance of the heating resistor or the contact electrode may be modified as required and is not limited to those shown in the above-mentioned embodiments. Additionally, the embodiments of the present invention utilize a simplified DC sputtering system for illustration but other types of equipment incorporated with the sputtering system are allowable. For example, a collimator or RF coils may be installed to increase covering efficiency of the superalloy film. Furthermore, the superalloy film may be formed by conventional deposition processes, such as evaporation, chemical vapor deposition (CVD), or physical vapor deposition (PVD).

Superalloy materials have several material properties of withstanding extreme temperatures, better strengthening, corrosion resistance, creep resistance at high temperatures, and rapid-thermal increase. For these reasons, superalloy material is a perfect material for the sputtering target in order to form the heating resistor of the present invention. The micro-heating apparatus having a heating resistor made of superalloy material has better reliability and longer lifetime than conventional micro-heating apparatus.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A superalloy micro-heating apparatus, comprising:
a substrate;
an isolation layer positioned on a front surface of the substrate;
a heating resistor positioned on the isolation layer, the heating resistor being made of superalloy materials; and
a contact electrode positioned on the heating resistor.

2. The superalloy micro-heating apparatus of claim 1, wherein the heating resistor has a pattern.

3. The superalloy micro-heating apparatus of claim 1, wherein the contact electrode is connected to an outer electro supply for providing current, and the current is converted to heat by the heating resistor.

4. The superalloy micro-heating apparatus of claim 1, wherein the superalloy materials comprise Inconel, Nimonic, Incoloy, Invar, Illium, NX-188, or combinations thereof.

5. A method of manufacturing a superalloy micro-heating apparatus, comprising:
providing a substrate and a superalloy-sputtering target, the substrate having an isolation layer and a patterned photoresist formed on a front surface thereof, and the superalloy-sputtering target being electrically connected to a cathode of a sputtering system;
performing a sputtering process to form a superalloy film on the surface of the isolation layer and the patterned photoresist; and
performing a lift-off process to remove the patterned photoresist and a part of the superalloy film deposited on the patterned photoresist so that the superalloy film is patterned to form a heating resistor.

6. The method of claim 5, wherein the sputtering process is performed with a plasma comprising helium or argon to sputter the superalloy on the surface of the isolation layer and the patterned photoresist and to form the superalloy film.

7. The method of claim 5, further comprising a method of manufacturing a contact electrode after the heating resistor is formed, wherein the method of manufacturing the contact electrode comprises steps of:
forming a second photoresist on a surface of the heating resistor;
performing a lithography process to pattern the second photoresist and to define a position and a pattern of the contact electrode;
performing a deposition process to form a metal layer covering the patterned second photoresist and a part of the surface of the heating resistor; and
performing a lift-off process to remove the patterned second photoresist to form the contact electrode.

8. The method of claim 5, wherein the superalloy-sputtering target comprises Inconel, Nimonic, Incoloy, Invar, Illium, NX-188, or combinations thereof.

9. A method of manufacturing a micro-heating apparatus, comprising:
providing a substrate and a superalloy-sputtering target, the substrate having an isolation layer, and the superalloy-puttering target being electrically connected to a cathode of a sputtering system;
performing a sputtering process to form a superalloy film on a surface of the isolation layer and a surface of the patterned photoresist; and
forming a patterned photoresist covering the superalloy film;
performing an etching process which utilizes the patterned photoresist as a mask to pattern the superalloy film; and
removing the patterned photoresist to expose the patterned superalloy film and form a heating resistor.

10. The method of claim 9, further comprising a method of manufacturing a contact electrode after the heating resistor is formed, wherein the method of manufacturing the contact electrode comprises steps of:
forming a second photoresist on a surface of the heating resistor;
performing a lithography process to pattern the second photoresist and to define a position and a pattern of the contact electrode;
performing a deposition process to form a metal layer covering the patterned second photoresist and a part of the surface of the heating resistor; and
performing a lift-off process to remove the patterned second photoresist to form the contact electrode.

11. The method of claim 9, wherein the superalloy-sputtering target comprises Inconel, Nimonic, Incoloy, Invar, Illium, NX-188, or combinations thereof.

12. The method of claim 9, wherein the sputtering process is performed with a plasma comprising helium or argon to sputter the superalloy on the surface of the isolation layer and the patterned photoresist and to form the superalloy film.
